(19) United States
(12) Patent Application Publication
(10) Pub. No.: US 2023/0268462 A1
(43) Pub. Date: Aug. 24, 2023

(54) FULLY TRANSPARENT ULTRAVIOLET OR FAR-ULTRAVIOLET LIGHT-EMITTING DIODES

(71) Applicant: The Regents of the University of California, Oakland, CA (US)

(72) Inventors: Christian J. Zollner, Goleta, CA (US); Michael Iza, Goleta, CA (US); James S. Speck, Santa Barbara, CA (US); Steven P. DenBaars, Goleta, CA (US); Shuji Nakamura, Santa Barbara, CA (US)

(73) Assignee: The Regents of the University of California, Oakland, CA (US)

(21) Appl. No.: 18/014,541

(22) PCT Filed: Jul. 9, 2021
(86) PCT No.: PCT/US2021/041042

§ 371 Date: Jan. 5, 2023

Related U.S. Application Data
(60) Provisional application No. 63/049,801, filed on Jul. 9, 2020.

(51) Int. Cl. H01L 33/32; H01L 33/62; H01L 33/06; H01L 33/14; H01L 33/22; H01L 25/075; H01L 33/00

(52) U.S. Cl. CPC H01L 33/325; H01L 33/62; H01L 33/06; H01L 33/14; H01L 33/22; H01L 25/0753; H01L 33/007

(57) ABSTRACT

A fully transparent UV LED or far-UV LED is disclosed, in which all semiconductor layers except the active region are transparent to the radiation emitted in the active region. The key technology enabling this invention is the transparent tunnel junction, which replaces the optically absorbing p-GaN and metal mirror p-contact currently found in all commercially available UV LEDs. The tunnel junction also enables the use of a second n-AlGaN current spreading layer above the active region (on the p-side of the device) similar to the current spreading layer already found below the active region (on the n-side of the device). Therefore, small-area and/or remote p- and n-contacts can be used, and light can be extracted from both the top-side and bottom-side of the device. This fully transparent semiconductor device can then be packaged using transparent materials into a fully transparent UV LED or far-UV LED with high brightness and efficiency.

### CROSS REFERENCE TO RELATED APPLICATIONS

This application claims the benefit under 35 U.S.C. Section 119(e) of the following co-pending and commonly-assigned application:

U.S. Provisional Application Ser. No. 63/049,801, filed on Jul. 9, 2020, by Christian J. Zollner, James S. Speck, Steven P. DenBaars, and Shuji Nakamura, entitled “FULLY TRANSPARENT ULTRAVIOLET OR FAR-ULTRAVIOLET LIGHT-EMITTING DIODES,” attorneys' docket number G&C 30794.0781USP1 (UC 2020-725-1);

which application is incorporated by reference herein.

### BACKGROUND OF THE INVENTION

### 1. Field of the Invention

This invention relates to a novel design for ultraviolet (UV) or far-UV light-emitting diodes (LEDs) that are fully transparent. In these devices, all semiconductor layers and other components, except for an active region, are transparent to the wavelength of light produced in the active region. Therefore, maximum light extraction efficiency is achieved, and a high power UV emitter is produced.

### 2. Description of the Related Art

This invention relates to the fabrication of devices using III-nitride based semiconductors layers. As used herein, the terms “III-nitride,” or more simply “nitride,” refer to any alloy composition of the (Ga,Al,In,B)N semiconductors having the formula Ga_{w}AlₓIn_{y}B_{z}N where:

0≤w≤1, 0≤x≤1, 0≤y≤1, 0≤z≤1, and w+x+y+z=1.

The III-nitride layers may be comprised of a single or multiple layers having varying or graded compositions, including layers of dissimilar (Al,Ga,In,B)N composition. Moreover, the layers may also be doped with elements, such as silicon (Si), germanium (Ge), magnesium (Mg), boron (B), iron (Fe), oxygen (O), and zinc (Zn).

The III-nitride layers may be grown in any crystallographic direction, such as on a conventional polar c-plane, or on a nonpolar plane, such as an a-plane or m-plane, or on any semipolar plane, such as {20-21}, {20-2-1}, {11-22} or {10-11}.

The III-nitride layers may be grown using deposition methods comprising metalorganic chemical vapor deposition (MOCVD), hydride vapor phase epitaxy (HVPE) or molecular beam epitaxy (MBE).

The usefulness of III-nitride layers, such as gallium nitride (GaN), and its ternary and quaternary compounds incorporating aluminum and indium (AlGaN, InGaN, AlInGaN), has been well established for the fabrication of visible and ultraviolet optoelectronic devices and high-power electronic devices.

Additionally, the development of AlGaN for short wavelength devices has enabled III-nitride based light emitting diodes (LEDs) and laser diodes (LDs) to overtake many other research ventures. Consequently, AlGaN based materials and devices have become the dominant material system used for ultraviolet light semiconductor applications.

### SUMMARY OF THE INVENTION

The present invention discloses a novel design for a UV or far-UV LED that is fully transparent, and therefore has very high efficiency. Fully transparent LEDs are known to give the highest possible light extraction efficiency for visible devices; however, no fully transparent UV LEDs exist. The present invention discloses the first and only fully transparent UV or far-UV LED, by eliminating all optically absorbing components of the UV or far-UV LED.

The semiconductor device layers of this LED must all be transparent to the emission wavelength, as is already common in the prior art, with the exception of the p-GaN hole injection layer and active region, which are optically absorbing. Instead of p-GaN, the fully transparent UV or far-UV LED contains a transparent tunnel junction, which is a highly doped p-n junction operated in reverse bias, injecting holes into the p-side of the LED via interband tunneling. This tunnel junction may contain polarization-enhanced structures, possibly including novel structures, such as scandium (Sc) containing compounds or nitride alloys containing some scandium. Additionally, the tunnel junction enables an n-type current spreading layer above the p-side of the device, eliminating the need for lossy metal mirrors, and instead enabling top-side emission, in addition to the already demonstrated bottom-side emission through the transparent substrate. This occurs because the metal contact to the p-side of the LED can be made much smaller than the emitting area, whereas the prior art requires full metal coverage of the emitting area.

In the preferred embodiment, the device is packaged using fully transparent materials, such as quartz, sapphire, or other UV-transparent materials, and in a way that enables both bottom-side and top-side emission. The device mounting and packaging is similar to the existing art for transparent visible LEDs, except that UV-transparent materials are used.

Several devices may be connected together on the transparent substrate to enable novel functionality. In the preferred embodiment presented herein, many devices may be connected in series, or in a bridge circuit configuration, so as to operate effectively under standard wall-plug AC current supplies without the need for costly and bulky conversion electronics and ballasts.

### BRIEF DESCRIPTION OF THE DRAWINGS

Referring now to the drawings in which like reference numbers represent corresponding parts throughout:

FIG. 1 is a flowchart that illustrates the steps for fabrication of a transparent UV LED or far-UV LED, according to one embodiment of the present invention.

FIGS. 2A and 2B are schematic drawings of a conventional UV LED.

FIGS. 3A, 3B and 3C are schematics of a transparent UV LED device, which does not have any p-GaN or lossy metal mirror.

FIGS. 4A and 4B are schematics of a transparent UV LED, mounted on a transparent plate to enable emission from top and bottom sides.

FIGS. 5A and 5B are schematics of a filament UV LED, making use of the fully transparent UV LED and enabling very high light extraction.

FIG. 6 is a sketch of a diode bridge circuit which allows UV LEDs to make use of an AC power supply.

FIG. 7A is a plot comparing voltage and output power versus injected current for a deep ultraviolet LED packaged using conventional and vertical geometries; FIG. 7B is a photograph of the vertical geometry of the UV LED; and FIG. 7C is a micrograph of the UV LED emission pattern taken in a conventional flat (on-wafer) geometry, showing the metal contact which makes up less than 50% of the emission area.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Overview

The present invention describes a high efficiency UV or far-UV LED device that is fully transparent, thereby enabling maximum light extraction efficiency. Specifically, the emission wavelength of the LED is below 400 nm (a UV-A LED), and more preferably, below 300 nm (a UV-B LED), below 280 nm (a UV-C LED) and below 230 nm (a far-UV LED).

Prior art in the UV LED industry makes use of several optically absorbing elements which diminish device efficiency and therefore power output. Furthermore, far-UV LEDs, which are very promising for skin-safe and eye-safe disinfection applications, are extremely inefficient and are not commercially available, due in part to the detrimental optical absorption of many device components. The present invention solves these problems by introducing novel device components that are fully transparent to replace the optically absorbing elements found in the prior art.

The fully transparent UV or far-UV LED is positioned on or above a transparent substrate. In the preferred embodiment, the LED is fabricated on a sapphire substrate due to its low cost, excellent optical and structural quality, and optical transparency throughout the spectral region of interest. In an alternative embodiment, semiconductor layers for the LED could be grown on some other substrate, and then transferred to a sapphire substrate.

High quality AlN layers can be grown on or above the sapphire substrate by a plurality of techniques, which are well described in the literature and industrially mature. The sapphire substrate may be flat, or patterned, or nano-patterned, and the AlN or AlGaN buffer may comprise a nano-porous buffer layer to enhance structural properties or allow lattice matched layers. The AlN and AlGaN layers may comprise conventional c-plane or novel semipolar or nonpolar orientations. Semipolar and nonpolar orientations may improve light extraction efficiency, carrier injection efficiency, and quantum efficiency.

Next, all UV LED or far-UV LED semiconductor layers, except the active region, are optically transparent. The prior art typically comprises mostly transparent layers; however, the p-side of the device often has optically absorbing hole-injection layers. Almost all currently commercially available UV LED devices contain absorbing p-GaN hole injection layers, as good electrical contacts cannot be made to p-AlGaN, and no current spreading occurs in p-AlGaN.

In the present invention, hole injection occurs via interband tunneling within a tunnel junction. Tunnel junctions show much promise in UV LEDs, because they eliminate the need for p-GaN (they also enable a much more efficient current spreading architecture, as described below). The tunnel junction may comprise a p-n junction structure with strongly doped p-type and n-type layers, superlattices, or graded layers on either side of the p-n junction, to improve performance via polarization-engineering and band-engineering.

Above the n-side of the tunnel junction (which is positioned above the p-side of the LED), an n-AlGaN current spreading layer may be deposited. The excellent electrical properties of transparent n-AlGaN (relative to p-AlGaN) allow the majority of the top-side of the device to be fully transparent, with only small regions contacted by metal ohmic contacts in an interdigitated or mesh contact configuration.

This “buried tunnel junction” structure is produced in such a way as to maintain the p-type conductivity of the p-type layers, either by preventing passivation or by activating the buried p-type layers after growth. For example, holes could be etched or formed by selective area masked regrowth of the n-AlGaN current spreading layer, so as to allow gas exchange with the buried tunnel junction layer. With the transparent n-AlGaN current spreading layer above the tunnel junction, efficient top-side emission adds to the already highly efficient bottom-side emission through the transparent substrate, without the need for lossy metal mirrors.

Finally, the transparent UV LED or far-UV LED is encapsulated and/or packaged in fully transparent materials, such as quartz, sapphire, ZnO, or any other desired transparent material. Then, the LED can be packaged and configured so as to maximize light extraction efficiency, in a plurality of configurations analogous to those for visible LEDs. In one possible embodiment enabled by the fully transparent substrate and device architecture, many UV LEDs or far-UV LEDs can be connected in series or in a bridge configuration, so as to make direct use of the AC voltage sourced by conventional wall-plug sockets. Another possible embodiment of the transparent design is in a filament configuration, enabling maximal light extraction in all directions.

At this time, UV-compatible encapsulant packaging materials are limited in availability, and performance and lifetime are not well known. In particular, there is no well-established and commercially available UV encapsulant that has been proven to withstand high optical power and high temperatures (above 50° C.). In the preferred embodiment, therefore, there is no encapsulant or other packaging material in contact with the UV LED; rather, the UV LED and transparent growth substrate are mounted within a transparent fixture, such as a quartz (or other transparent material) enclosure filled with inert gas, which removes heat and maintains reliability of the UV LEDs.

Technical Description

A transparent substrate is used so that light may be emitted through the bottom of the substrate. In the preferred embodiment, a sapphire substrate is used. High quality AlN layers can be grown on or above the sapphire substrate by a plurality of techniques, which are well described in the academic literature and industrially mature. The sapphire substrate may be flat, or patterned, or nano-patterned, and the AlN or AlGaN buffer may comprise a nano-porous buffer layer to enhance structural properties or allow lattice matched layers. For example, nanoporous AlGaN could be used to enable low threading dislocation density device layers, while also acting as a compliant pseudo-substrate layer for lattice-matched growth of active region layers. This would reduce the piezoelectric fields in the active region, which are thought to reduce device efficiency. Unlike bulk AlN substrates which are both costly and optically absorbing due to impurities, AlN or AlGaN buffer layers including nanoporous layers are fully transparent. However, if fully transparent AlN substrate wafers are produced in the future, these could be used as well. In an alternative embodiment, absorbing substrates, such as AlN or SiC, could be used for growth, and then the epitaxial semiconductor layers could be transferred onto a transparent substrate via wafer bonding.

Unlike these alternative substrate options, sapphire is currently the best option due to transparency and low cost, and is thus taken to be the preferred embodiment of the present invention. After or before growth, the back-side of the substrate could be roughened to increase light extraction from the bottom of the substrate. Throughout this disclosure, the phrase “growth substrate” or “as-grown substrate” is used to refer to the preferred embodiment in which the sapphire substrate which is used as the template for growth of semiconductor device layers, also serves as the final mounting piece for the LED in the fixture. This simplifies processing and eliminates the need for optically absorbing adhesives, metal bonds, or other lossy elements. In an alternative embodiment, the sapphire mounting piece or submount could be a separate sapphire wafer or chip which was not the sapphire piece used for growth of semiconductor layers.

One of the key technologies for the invention of the fully transparent UV LED or far-UV LED is the fully transparent tunnel junction. A tunnel junction is a strongly doped p-n junction operated in reverse bias, wherein electrons tunnel from the valence band of the p-side into the conduction band of the n-side, thereby injecting holes into the p-side of the device.

A fully transparent tunnel junction could comprise AlGaN and AlN layers, or very thin GaN layers. Due to carrier confinement, properly designed GaN layers thinner than a few nanometers do not efficiently absorb light and therefore remain fully transparent at the wavelengths of interest.

Furthermore, strongly p-doped graded AlGaN or AlN may be used to form the p-side of the tunnel junction. Such a layer would take advantage of the strong polarization fields due to differences in spontaneous and piezoelectric polarization between Al(Ga)N layers of differing composition, to produce two-dimensional or three-dimensional hole-gas regions. These regions are known to produce excellent ohmic contacts to p-AlN, and are expected to produce excellent tunnel junction layers as well.

Care must be taken to adequately design the tunnel junction to be both fully transparent and electrically efficient, so that the tunnel junction region may comprise a plurality of uniform, superlattice, or graded-composition layers with various doping levels and thicknesses.

The most important aspect of the tunnel junction is that, in addition to efficiently injecting holes into the p-side of the device, the tunnel junction allows the addition of another n-type current spreading layer above the tunnel junction. Since n-AlGaN is both highly conductive and fully transparent, this novel device design allows the LED device to contain transparent current spreading layers both below (on the “n-side” of) and above (on the “p-side” of) the active region. For the buried tunnel junction to remain effective, the p-type materials must remain conductive. Therefore, the n-AlGaN current spreading layer above the tunnel junction may be patterned (either using masked dry etching post-growth, or using patterned regrowth above the p-type layers of the tunnel junction) with openings to allow gas exchange to enable p-AlGaN activation. This is another key technology enabling light extraction through both the top and bottom of the device.

Metal contacts must be made to the n-type current spreading layers on either side of the active region (i.e., adjacent to the emitting area, rather than directly above or below it), and naturally these metal contacts are optically absorbing. However, because of the current spreading properties of n-AlGaN (in contradistinction with p-AlGaN or p-GaN), these contacts can be made relatively small and can be located to the side of the device, or otherwise designed in such a way as to cause minimal light absorption. In the preferred embodiment, the p-side contacts (the metal located above the emitting area) are made much smaller than the emitting area of the device, so that optical absorption is negligible. This may be achieved by a single, small p-contact pad or using a mesh contact. The size of both contact metallization regions (including the n-side contact and p-side contact) should be minimized in the preferred embodiment of the transparent UV LED.

The invention of the fully transparent UV LED or far-UV LED also allows for the invention of novel devices comprising many LEDs integrated into a single device. For example, many UV LEDs or far-UV LEDs could be connected in series, or in a diode bridge configuration, so as to utilize the high-voltage AC power supplies commonly found in wall-plug sources. These series configurations could comprise planar or filamentary configurations, the latter configuration enabling maximal light extraction in all directions. Alternatively, the fully transparent device could be packaged within an optical waveguiding or “light pipe” structure so as to act as a highly efficient point source for disinfection applications in which point sources are needed. However, the preferred embodiment makes use of no encapsulation or adhesive material in contact with the LED, such that only the transparent growth substrate is in contact with the UV LED. Use of the sapphire growth substrate avoids the need for encapsulation or adhesives which may have poor performance or lifetime under high power UV illumination and elevated temperatures.

The fully transparent LED, in the preferred embodiment, is also mounted inside of a transparent enclosure, such as a luminaire or bulb or other enclosure. This transparent enclosure may be made of quartz, or specialized UV-grade glass, or any other transparent material. This enclosure may also be filled with an inert gas, such as argon, nitrogen or any other desired filling gases, which remove heat from the device by convection without leading to material degradation at elevated temperatures.

Process Steps In this section, process steps for producing one possible embodiment of a fully transparent UV LED are presented. It is to be understood that other similar devices could be produced, or that the same device may be produced by differing methods, without departing from the scope of the present teaching.

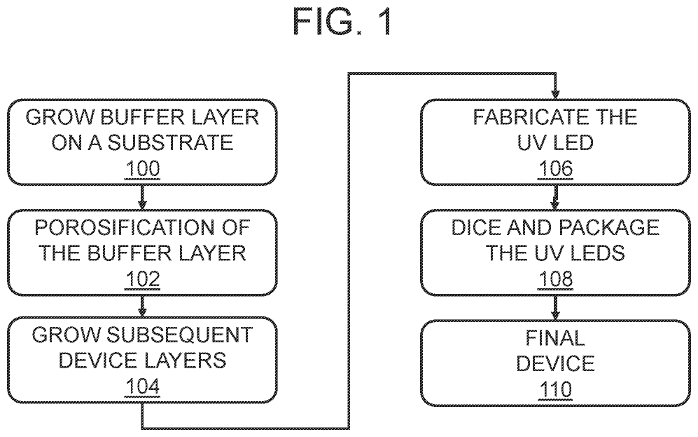

FIG. 1 is a flowchart illustrating the steps for fabricating a fully transparent UV LED as disclosed herein. Similar steps may also be used for the production of a far-UV LED. The growth method used in the preferred embodiment is MOCVD, although other methods including HVPE, MBE or any other desired growth method could be used.

Block 100 represents the step of growing a transparent buffer layer upon a substrate which will act as the template for subsequent UV LED layers, using MOCVD or some other desired technique. In one embodiment, the layers of the LED are grown on a sapphire substrate, wherein the sapphire substrate comprises a flat sapphire substrate, a micro-patterned sapphire substrate, or a nano-patterned sapphire substrate, or a back-side of the sapphire substrate may be roughened. In another embodiment, an alternative substrate may be used as long as (1) the substrate is fully transparent or (2) the substrate, if absorbing, is removed in later processing steps. In one embodiment, the transparent buffer layer may comprise an AlN buffer layer, or an AlGaN layer above or instead of an AlN buffer layer.

Block 102 represents the optional step of electrochemical porosification of the AlN or AlGaN buffer layer, so that the layers of the LED include one or more porous AlN or AlGaN layers. This can be accomplished by applying a voltage to the layer while submerging it in a suitable electrolyte solution. Porosification has been recently shown to improve device quality by acting as a compliant layer for lattice-matched device layers, and the porous AlN or AlGaN layers serve as a compliant pseudo-substrate for subsequent growth of relaxed or lattice matched device layers. It may also improve material quality by reducing dislocation density, and the porous AlN or AlGaN layers serve as a dislocation density reduction structure. This process may improve structural quality of subsequent device layers without the need for optically absorbing bulk AlN substrates. It may also allow for lattice matched or relaxed pseudo-substrates.

Block 104 represents the step of growing subsequent device layers, wherein the III-nitride based UV LED is comprised of one or more III-nitride layers, and each of the III-nitride layers includes at least some aluminum (Al) and nitrogen (N). A plurality of differing nitride layers may be grown in order to produce an efficient LED device, including doped layers, active layers, polarization enhanced layers, superlattice or graded layers, or any other desired layer types.

By way of example, the following general layer sequence is considered: n-AlGaN current spreading layer, AlGaN multi-quantum well (MQW) active region layers, p-AlGaN or AlN electron blocking layer (EBL), p-type AlGaN superlattice or graded or otherwise polarization enhanced p-type hole-supply, tunnel junction including heavily doped and/or polarization enhanced p+ tunneling layer and heavily doped and/or polarization enhanced n+ tunneling layer, and n-AlGaN current spreading layer.

The tunnel junction is a III-nitride tunnel junction used to inject holes into a A-side of the LED. The tunnel junction may include a superlattice, interface, or compositionally graded region, which produces a spatially varying electric polarization. Polarization effects of the spatially varying electric polarization enhance performance of p-type layers within the tunnel junction, for example, an Mg doped AlN layer may be used to form a hole-gas tunnel junction layer of the tunnel junction. Polarization effects of the spatially varying electric polarization enhance performance of n-type layers within the tunnel junction. Polarization effects of the spatially varying electric polarization enable use of undoped semiconductor layers within the tunnel junction, via polarization doping or modulation doping. Some other element, such as B, Sc or any other novel element, may introduced into the III-nitride material of the LED, in order to enhance polarization effects, or tunnel junction performance, or LED performance.

There may be one or more holes or openings in a surface of the LED that expose one or more p-type layers below the surface of the LED, including a p-type layer of the tunnel junction. These holes or openings enable activation of the p-type layers.

A transparent current spreading layer, such as n-AlGaN, may be grown on or above the tunnel junction. The transparent current spreading layer enables remote n-contacts so that light emission may occur through a top of the LED, in addition to emission through a bottom of the LED and a transparent substrate.

Block 106 represents the step of fabricating the UV LED using various processing technologies including mesa etching, sidewall or surface passivation using oxide or nitride film deposition (for example, deposition of silicon-oxide or aluminum-oxide layers by sputtering or atomic layer deposition (ALD)), and metal contact deposition, patterning, and annealing, as needed.

For example, common contacts could be used in order to form a planar parallel array of diodes. In another possible embodiment, the metallization is patterned so as to form a series or diode bridge configuration.

Preferably, a total area of contact metal of the LED is less than 50% of an emitting area of the LED. In one example, a total area of contact metal on or above a p-type layer of the LED comprises an area less than 50% of an emitting area of the LED. In another example, a total area of contact metal on a n-type layer of the LED comprises an area less than 50% of an emitting area of the LED.

In one embodiment, a top and/or bottom surface of the LED may be roughened to enhance light extraction from the LED.

In one embodiment, the layers of the LED may be grown on a substrate, which is later removed during device processing.

Block 108 represents the step of packaging the device, for example, by dicing the wafer into pieces (which may comprise individual LED dies, multi-LED planar arrays, multi LED filamentary arrays, or any other desired configuration), and packaging the LED devices using fully transparent packaging.

In one embodiment, a plurality of interconnected LEDs are arranged in a parallel, series, or diode bridge configuration, while remaining on the transparent growth substrate. The LEDs may be connected in parallel so as to enable high power and low voltage operation of the LEDs, or the LEDs may be connected in series so as to enable high voltage and low current operation of the LEDs. The LEDs may be connected in the diode bridge configuration so as to enable direct use of a high voltage AC power supply for the LEDs. The LEDs may be connected in a planar geometry for high power output from the LEDs. The LEDs may be connected in a linear or filamentary geometry to enable maximal light output in all directions from the LEDs.

Finally, this step may include enclosing the LED(s) in a transparent material, such as quartz or transparent resin or other transparent material, if desired, and there may be an inert gas, including but not limited to, argon or nitrogen, inside the transparent material. The transparent material may be shaped to enhance light extraction, for example, wherein a shape of the transparent material is an inverted cone or inverted truncated cone shape.

Block 110 represents the final product, namely, at least one fully transparent III-nitride based LED with an emission wavelength of less than 400 nm, wherein layers of the LED except active region layers are transparent to the emission wavelength.

In various embodiments, the LED has an emission wavelength below 300 nm and comprises a UV-B LED; and/or the LED has an emission wavelength below 280 nm and comprises a UV-C LED; and/or the LED has an emission wavelength below 230 nm and comprises a far-UV LED.

This block also includes operating such a device in various applications, for example, wherein the light emitted by the LED has a wavelength and power such that it acts as a germicidal radiation source.

Note that this embodiment allows for steps to be modified, omitted, repeated or added as desired.

Device Structures

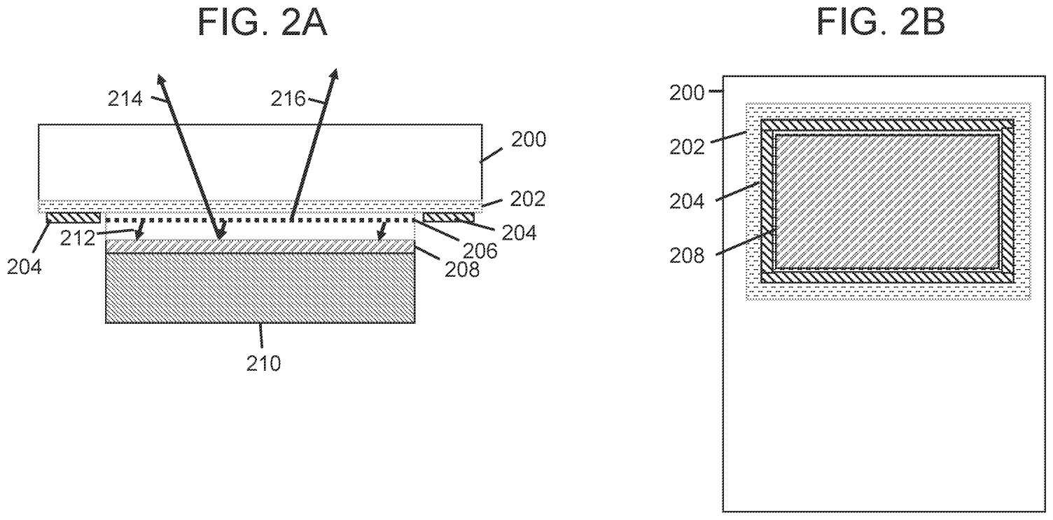

FIGS. 2A and 2B are schematics of a UV LED, showing the substrate, semiconductor layers, metal contacts, and submount chip, wherein FIG. 2A is a cross-sectional view of the UV LED and FIG. 2B is a plan view of the UV LED. Element 200 is the transparent mounting plate or substrate. Element 202 is the n-AlGaN current spreading layer, which enables remote contacts 204 to the n-side of the LED (that is, adjacent to the emitting area, rather than directly above it). Element 206 represents the active region. Element 208 represents the p-contact to the LED, including both an optically absorbing p-GaN contact layer, which is needed to make electrical contact to the p-side of the device, as well as a p-side metal mirror (i.e., the metal layer which is located above the emitting area) with a reflectivity significantly less than 100% leading to loss of optical power. The lack of current spreading layer precludes the formation of remote contacts, so that light cannot be emitted from the A-side (downward direction) of the device. That is, the p-side or top-side contact 208 covers nearly the entire emitting area of the device. Element 210 represents the submount wafer needed in the case of flip-chip processing, which is often used. Element 212 represents the UV light which is absorbed at the p-contact 208, and elements 214 and 216 represent light, wherein light 214 is reflected by the mirror 208 and light 216 is emitted directly upward, respectively. Furthermore, the light 214, 216 can only be extracted in one direction, e.g., upward, so that most light emission is not single-pass light extraction but rather light which has reflected many times, compounding the optical absorption loss from the mirror and p-GaN 208.

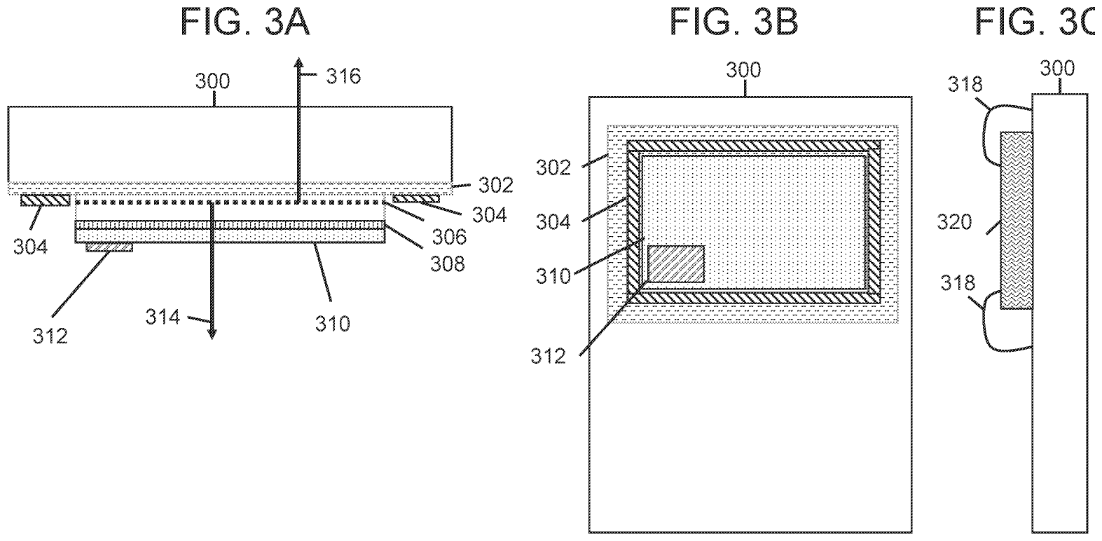

FIGS. 3A, 3B and 3C are schematics of a transparent UV LED, which does not have any p-GaN or lossy metal mirror, wherein FIG. 3A is a cross-sectional view of the transparent UV LED, FIG. 3B is a plan view of the transparent UV LED, and FIG. 3C is a side view of the transparent UV LED. While the device shown is not flip-chip processed, it is drawn in an inverted configuration as compared with FIGS. 2A and 2B. Elements 300-306 are the same as those illustrated by elements 200-206 in FIGS. 2A and 2B, respectively, namely, transparent mounting plate or substrate 200, n-AlGaN current spreading layer 202, n-contacts 204, and active region 206. Element 308 represents a tunnel junction, which enables hole injection into the p-side of the device without any optically absorbing layers. Element 310 represents an n-AlGaN current spreading layer, which may be grown above the tunnel junction 308.

Element 312 represents a p-side contact (which is a metal contact to the n-type current spreading layer 310). Due to the current-spreading properties of the n-AlGaN layer 310, the p-side contact 312 metal (i.e., the metal above the active region 306) can be much smaller than the emitting area, comprising either a remote contact pad (as illustrated) or a mesh contact pattern. In an alternative embodiment, the electrical contact could be made directly to an n-AlGaN layer of the tunnel junction 308.

Because it has a tunnel junction 308 and current spreading layer 310, all electrical contacts 312 can be made remotely (not shown in the figure), and light is emitted from both the top and bottom of the device. Elements 314 and 316 represent light emitted through the p-side and n-side of the device, illustrating the lack of any absorbing or lossy element in either of the predominant light-emission directions. While there will be some amount of reflection, most of the light is emitted on the first pass, and light extraction efficiency is very high.

The side view of the UV LED in FIG. 3C includes the semiconductor device region 320, the wire bonds 318, and sapphire substrate or mounting piece 300. The semiconductor device 320 comprises, e.g., all of the elements 302-312. The wire bonds 318 could be replaced with lithographically defined metal leads, indium or other metal or solder-based metallization, or any other desired electrical contact mechanism.

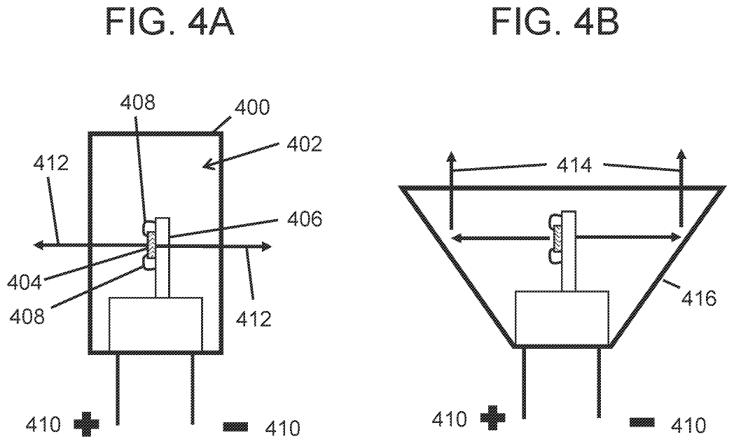

FIGS. 4A and 4B are schematics of a light fixture using the fully transparent UV LED device, wherein both FIGS. 4A and 4B are cross-sectional views of the fully transparent UV LED. The device is encapsulated or contained in a transparent container 400 made of quartz, UV-grade resin, or some other transparent material, which is filled with an inert gas, such as Ar 402. In the preferred embodiment, the UV LED 404 remains on the as-grown sapphire substrate 406, which becomes the transparent mounting plate, so that no adhesive is needed to bond the device 404 to the plate 406. Metal wiring may be affixed by wire bonding 408 or patterned directly into the sapphire growth substrate 406, or some combination of wire bonding, lithographic metallization, and soldering may be used. Electrical connections are made using leads 410 and should comprise a DC electrical current for single device operation.

In FIG. 4A, light is extracted in two directions as represented by element 412. In FIG. 4B, the enclosure geometry is such that light is reflected for unidirectional emission 414. This can be achieved by, e.g., optimizing the angle of the walls of the enclosure 416. In the preferred embodiment, the enclosure 416 geometry is that of an inverted truncated cone shape, so that light emission could be directed in one preferred direction.

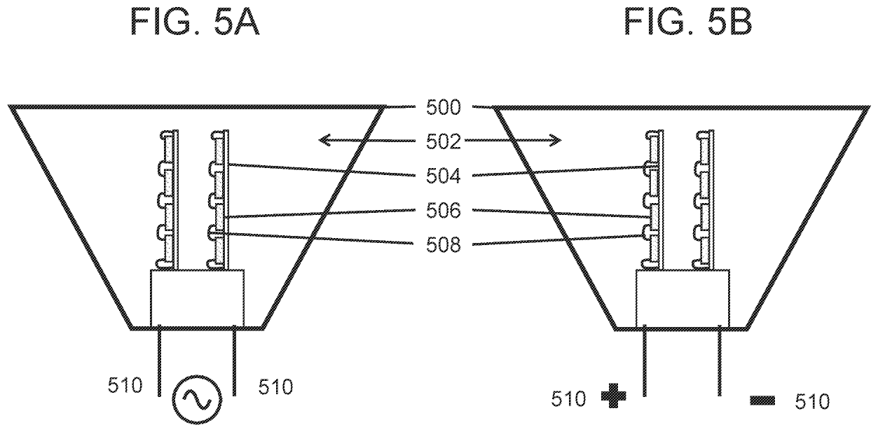

FIGS. 5A and 5B are schematics of a filament UV LED, making use of the fully transparent UV LED and enabling very high light extraction, wherein both FIGS. 5A and 5B are cross-sectional views of the filament UV LED. In this device, many LEDs are connected in series, in parallel, or in a diode bridge configuration, such that any choice of power supply including high voltage AC can be utilized without the need for driving circuitry. Elements 500-510 are similar to those depicted in elements 400-410, respectively, in FIGS. 4A and 4B, namely, fixture, container or enclosure 500, which is filled with an inert gas 502, a UV LED 504 that remains on the as-grown sapphire substrate 506, which becomes the transparent mounting plate, wire bonding 508, and leads 510.

The filament bar style LED bars with many LEDs 504 per bar should be located within the fixture 500 in such a way that UV light emitted in one device 504 is not absorbed in the active region of a neighboring device 504. Thus, the two bars shown in FIGS. 5A and 5B should be positioned in a staggered geometry (in the direction of the page) so that they do not directly shadow each other. Moreover, no UV-absorbing materials are used, which may obstruct light extraction out of the transparent enclosure.

Diode Bridge Circuit

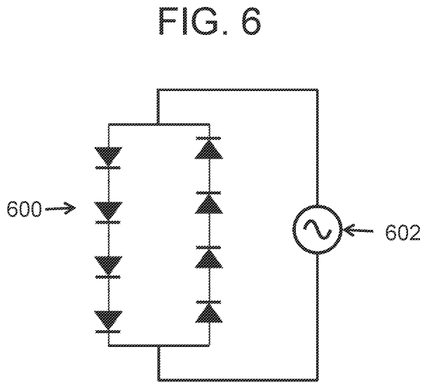

FIG. 6 is a sketch of a diode bridge circuit 600 which would allow the diodes (LEDs) to make use of an AC power supply 602, as the two branches of the bridge will be on in alternation. If multiple diodes are connected in series on each branch, such that the total operating voltage of the series circuit is similar to that supplied by a high voltage source, then the diodes can be operated simultaneously for high light power output by a high voltage wall-plug power supply without the need for any power conversion or driving circuitry. The number of diodes per bridge, the number of bridges in parallel, and all other details of the circuit 600 may differ from that depicted in this illustration, which is to be understood as a conceptual sketch for teaching purposes, and which should not be understood as a circuit diagram or design.

Experimental Data

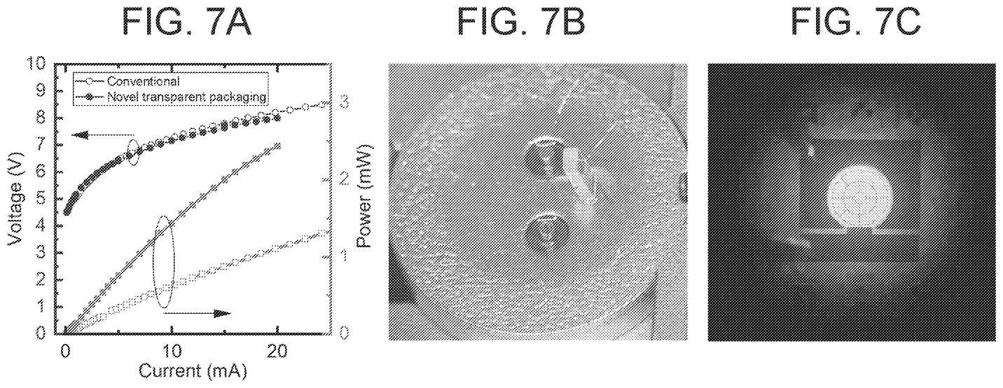

Experimental data for a device similar to that shown in FIG. 4A is shown in FIGS. 7A, 7B and 7C. This device includes a semi-transparent p-side metallization in place of a tunnel junction in order to demonstrate the benefits of this novel device geometry. Using the vertical mounting scheme with bi-directional light emission, output power for a deep-UV device is improvement twofold.

Specifically, FIG. 7A is a plot comparing voltage and output power versus injected current for a deep ultraviolet LED packaged using conventional and vertical geometries. The novel vertical geometry provides a 100% increase in light output power. Both devices in this data set use a thin metal semi-transparent contact for demonstration purposes; with a fully transparent tunnel junction contact and/or advanced encapsulation as disclosed below, the light extraction enhancement is expected to be much greater.

FIG. 7B is a photograph of the vertical geometry of the UV LED, and FIG. 7C is a micrograph of the UV LED emission pattern taken in a conventional flat (on-wafer) geometry, showing the metal contact which makes up less than 50% of the emission area.

Advantages and Improvements

The present invention discloses a fully transparent UV LED or far-UV LED device. The prior art in UV LEDs does not use fully transparent device layers, nor does it use fully transparent electrical contact layers or packaging materials.

The optical absorption of UV LED components is detrimental for two reasons: firstly, because it reduces the light extraction efficiency, and thus the total wall-plug efficiency, of the devices, and secondly, because all optical absorption processes lead to: (1) heat generation which must be managed on a systems-level, or (2) degradation as is the case in conventional organic encapsulation materials which degrade structurally and optically with exposure to UV, or (3) a combination of both heating and degradation).

Organic materials for use as adhesive or encapsulant applications in UV devices exist, but they have limited lifetime and performance. Dramatic reductions in optical absorption and improvements in device reliability can be achieved if these organic materials are eliminated, and only fully transparent inorganic materials, such as sapphire, quartz, or other highly transparent materials are used.

Another detrimental area of optical absorption is within the p-side of the diode structure and limits the performance of all currently commercially available UV LED devices. As discussed in previous sections, the optically absorbing p-contact elements are necessary to achieve hole injection in conventional structures but are unable to produce efficient hole injection in far-UV devices, so that no far-UV LEDs are commercially available at this time.

There is a need for a fully transparent UV LED in order to increase device efficiency and lifetime, and for a fully transparent far-UV LED to enable this technology to reach a much needed market application in skin- and eye-safe disinfection. The key technology enabling the fully transparent UV LED or far-UV LED is the transparent tunnel junction. The tunnel junction replaces the optically absorbing p-GaN and metal mirror contact structures with a fully transparent and highly conductive n-AlGaN layer. Highly conductive n-AlGaN is the material which already provides current spreading on the n-side of the device, enabling remote n-contacts. Thus, in addition to efficiently injecting holes, the tunnel junction allows the introduction of n-AlGaN on the p-side of the device, so that current spreading and small, remote p-contacts (i.e., the metal above the emitting area) are made possible.

The contact metal absorbs the LED light from the emitting region, so a smaller area of contact metal is better. The area of contact metal refers to both n-type Ohmic contacts and p-type Ohmic contacts. The total area of contact metal for both n-type Ohmic contacts and p-type Ohmic contacts should be minimized to minimize the absorption of the LED light by the metal. This is especially true for the area of metal contact in the p-type region located on or above the emitting layers, where the area of metal contact should be minimized as much as possible.

Finally, the fully transparent UV LED and far-UV LED devices enable novel device architectures including planar or filamentary arrays of devices. For instance, devices could be connected in series or in a diode bridge configuration so as to make direct use to the high-voltage AC power supplied to most conventional wall-plug outlets, without the need for costly and bulky electronics for AC-DC conversion, thermal management, etc.

References

The following patents are incorporated by reference herein:

(1) U.S. Pat. No. 7,687,813 B2, issued Mar. 30, 2010, to Nakamura et al., and entitled “STANDING TRANSPARENT MIRRORLESS LIGHT EMITTING DIODE.”

(2) U.S. Pat. No. 7,781,789 B2, issued Aug. 24, 2010, to DenBaars et al., and entitled “TRANSPARENT MIRRORLESS LIGHT EMITTING DIODE.”

(3) U.S. Pat. No. 8,294,166 B2, issued Oct. 23, 2012, to Nakamura et al., and entitled “TRANSPARENT LIGHT EMITTING DIODES.”

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A device, comprising:
at least one III-nitride based ultraviolet (UV) light-emitting diode (LED) with an emission wavelength of less than 400 nm, wherein layers of the LED except active region layers are transparent to the emission wavelength.

2. The device of claim 1, wherein a total area of contact metal of the LED is less than 50% of an emitting area of the LED.

3. The device of claim 1, wherein a total area of contact metal on or above a p-type layer of the LED comprises an area less than 50% of an emitting area of the LED.

4. The device of claim 1, wherein a total area of contact metal on a n-type layer of the LED comprises an area less than 50% of an emitting area of the LED.

5. The device of claim 1, wherein a III-nitride tunnel junction is used to inject holes into a p-side of the LED.

6. The device of claim 5, wherein the tunnel junction includes a superlattice, interface, or compositionally graded region, which produces a spatially varying electric polarization.

7. The device of claim 6, wherein polarization effects of the spatially varying electric polarization enhance performance of p-type layers within the tunnel junction.

8. The device of claim 7, wherein an Mg doped AlN layer is used to form a hole-gas tunnel junction layer of the tunnel junction.

9. The device of claim 6, wherein polarization effects of the spatially varying electric polarization enhance performance of n-type layers within the tunnel junction.

10. The device of claim 6, wherein polarization effects of the spatially varying electric polarization enable use of undoped semiconductor layers within the tunnel junction, via polarization doping or modulation doping.

11. The device of claim 5, wherein one or more holes or openings in a surface of the LED expose one or more p-type layers below the surface of the LED, including a p-type layer of the tunnel junction.

12. The device of claim 5, wherein a transparent current spreading layer comprised of n-AlGaN is grown on or above the tunnel junction.

13. The device of claim 12, wherein the transparent current spreading layer enables remote p-contacts so that light emission may occur through a top of the LED, in addition to emission through a bottom of the LED and a transparent substrate.

14. The device of claim 1, wherein the layers of the LED are grown on a sapphire substrate.

15. The device of claim 14, wherein the sapphire substrate comprises a flat sapphire substrate, a micro-patterned sapphire substrate, or a nano-patterned sapphire substrate.

16. The device of claim 14, wherein a back-side of the sapphire substrate is roughened.

17. The device of claim 1, wherein a top and/or bottom surface of the LED is roughened.

18. The device of claim 1, wherein the layers of the LED are grown on another substrate which is removed during device processing.

19. The device of claim 1, wherein layers of the LED include one or more porous AlN or AlGaN layers.

20. The device of claim 1, wherein the at least one LED comprises a plurality of interconnected LEDs.

21. The device of claim 19, wherein the plurality of interconnected LEDs are connected to a diode bridge circuit so as to enable direct use of a high voltage AC power supply for the plurality of interconnected LEDs.

22. The device of claim 1, wherein the LED is mounted inside a transparent material and there is an inert gas inside the transparent material.

23. A method, comprising:
fabricating at least one III-nitride based ultraviolet (UV) light-emitting diode (LED) with an emission wavelength of less than 400 nm, wherein layers of the LED except active region layers are transparent to the emission wavelength.

24. A method, comprising:
operating at least one III-nitride based ultraviolet (UV) light-emitting diode (LED) with an emission wavelength of less than 400 nm, wherein layers of the LED except active region layers are transparent to the emission wavelength.
